(19) United States
(12) Patent Application Publication
(10) Pub. No.: US 2026/0010300 A1
(43) Pub. Date: Jan. 8, 2026

(54) STORAGE DEVICE PERFORMING PRE-PROGRAM OPERATION AND PROGRAM METHOD THEREOF

(71) Applicant: SAMSUNG ELECTRONICS CO., LTD., Suwon-si (KR)

(72) Inventors: Changon Lee, Suwon-si (KR); Eun Chu Oh, Suwon-si (KR); Wan-Soo Choi, Suwon-si (KR)

(21) Appl. No.: 18/988,551

(22) Filed: Dec. 19, 2024

(30) Foreign Application Priority Data
Jul. 8, 2024 (KR) 10-2024-0089366

(51) Int. Cl. G06F 3/06; G06F 12/02

(52) U.S. Cl. CPC G06F 3/0625; G06F 3/0659; G06F 3/0679; G06F 12/0246; G06F 2212/7202

(57) ABSTRACT

An example program method of a non-volatile memory device comprises receiving a write request of multi-page data from a host, comparing an available memory capacity of a digest memory with a threshold, setting a write mode of the non-volatile memory device to a pre-program operation mode based on the available memory capacity being greater than or equal to the threshold, and programming the multi-page data into a pre-program block of the non-volatile memory device.

### CROSS-REFERENCE TO RELATED APPLICATION

This application claims priority under 35 U.S.C. § 119 to Korean Patent Application No. 10-2024-0089366 filed on Jul. 8, 2024, in the Korean Intellectual Property Office, the disclosures of which are incorporated by reference herein in their entireties.

### BACKGROUND

A storage device stores data under the control of a host device such as a computer, smart phone, or smart pad. Storage devices include hard disk drives (hereinafter referred to as HDDs) that use magnetic disks as storage media, solid state drives (hereinafter referred to as SSDs) that use semiconductor memory as storage media, and memory cards.

Storage devices that use non-volatile memory devices use a management mode to increase the efficiency of data backup of the storage device performed in the event of sudden power off (hereinafter referred to as SPO). For example, a program method is also used for efficient backup of programmed data in a sudden power off SPO situation. Technologies are being introduced to reduce the size of backup data in order to efficiently use the limited energy provided from the auxiliary power supply.

### SUMMARY

Implementations of the present disclosure provides a non-volatile memory device having a high-bandwidth input/output pad capable of high-speed data input/output.

In general, according to some aspects, a program method of a non-volatile memory device comprises receiving a write request of multi-page data from a host, comparing an available memory capacity of a digest memory with a threshold, setting a write mode of the non-volatile memory device to a pre-program operation mode if the available memory capacity is greater than or equal to the threshold, and programming the multi-page data into a pre-program block of the non-volatile memory device.

In general, according to some aspects, a storage device comprises a non-volatile memory device provided as a storage medium of the storage device, a write buffer configured to temporarily store write data requested to be written from a host, a digest memory configured to store digest data for writing the write data to the non-volatile memory device in a pre-program operation mode, and a storage controller configured to, determine a program mode of the write data as a pre-program operation mode when an available memory capacity of the digest memory is greater than or equal to a threshold value, program the write data in a first area of the non-volatile memory device according to the pre-program operation mode, and generate the digest data corresponding to the write data.

In general, according to some aspects, a program method of a storage device comprises receiving a write request from a host, checking an available memory capacity of a digest memory, setting a write mode of a non-volatile memory device to a pre-program mode if the available memory capacity is greater than a threshold value, programming the write requested multi-page data into a pre-program block of the non-volatile memory device, generating digest data from the multi-page data, storing the digest data in the digest memory, and transmitting a completion message for the write request to the host without re-programming the multi-page data.

### BRIEF DESCRIPTION OF THE DRAWINGS

The above and other objects and features of the present disclosure will become apparent by describing in detail implementations thereof with reference to the accompanying drawings.

FIG. 1 is a block diagram showing an example of a storage system.

FIG. 2 is a block diagram showing an example of a storage device.

FIG. 3 is a block diagram showing an example of a storage controller of FIG. 2.

FIG. 4 is an exemplary block diagram of a non-volatile memory device of FIG. 2.

FIG. 5 is a circuit diagram showing an exemplary structure of a memory block constituting the cell array of FIG. 4.

FIG. 6 is an example diagram briefly showing a data state of a memory cell and digest data according to a pre-program operation of the present disclosure.

FIG. 7 is a diagram showing an exemplary method of generating digest data.

FIG. 8 shows an example relationship between a pre-program block and a digest memory according to the pre-program operation of the present disclosure.

FIG. 9 is a diagram showing an example of an operation of a storage device during a pre-program operation.

FIG. 10 is a flowchart showing an example of a control operation of a storage controller for a pre-program operation of the present disclosure.

FIG. 11 is an example flowchart showing an implementation for processing a write request received in a pre-program operation mode state.

FIG. 12 is a drawing showing an example of a re-programming procedure of step S240 of FIG. 11 in more detail.

FIG. 13 is an example flowchart showing an implementation for processing a write request received in a pre-program operation mode state.

FIG. 14 is a flowchart briefly showing an example of a method for programming user data in a pre-program operation mode.

FIG. 15 is a flowchart showing an example of a method for processing a read request for pre-programmed data of the present disclosure.

FIG. 16 is a block diagram showing an example of a storage controller of FIG. 2.

### DETAILED DESCRIPTION

It is to be understood that both the foregoing general description and the following detailed description are exemplary, and it is to be considered that an additional description of the present disclosure is provided. Reference signs are indicated in detail in implementations of the present disclosure, examples of which are indicated in the reference drawings. Wherever possible, the same reference numbers are used in the description and drawings to refer to the same or like parts.

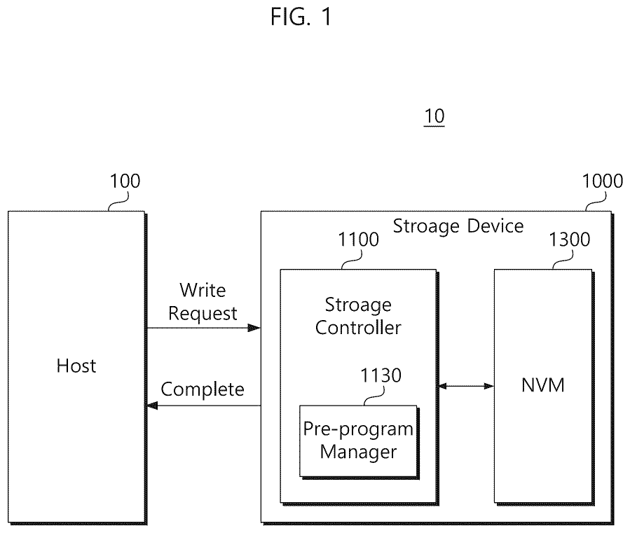

FIG. 1 is a block diagram showing an example of a storage system. The storage system 10 may include a host 100 and a storage device 1000.

The host 100 may manage and process various operations of the storage system 10. The host 100 may transmit a read or write request to the storage device 1000. The host 100 may perform various arithmetic operations/logical operations for accessing the storage device 1000. For example, the host 100 may include one or more processor cores. The host 100 may be implemented using a dedicated circuit such as a field programmable gate array FPGA or an application specific integrated circuit ASIC, or may be implemented as a system on chip SoC. The host 100 may include a general-purpose processor, a dedicated processor, or an application processor. The host 100 may be the processor itself, or an electronic device or system including the processor.

The storage device 1000 may include a storage controller 1100 and a non-volatile memory device 1300. The storage controller 1100 may program data in the non-volatile memory device 1300 in response to a write request from the host 100. Alternatively, the storage controller 1100 may read data stored in the non-volatile memory device 1300 in response to a read request from the host 100. To this end, the storage controller 1100 may manage a mapping table that defines a correspondence between a logical address and a physical address of data stored (or to be stored) in the non-volatile memory device 1300.

In addition, the storage controller 1100 may include a pre-program manager 1130. When the pre-program manager 1130 receives a write request from the host 100, it can set the program mode of the non-volatile memory device 1300 to the pre-program operation mode. When set to the pre-program operation mode, the non-volatile memory device 1300 does not perform a re-program operation procedure for the pre-programmed data. In other words, the non-volatile memory device 1300 set to the pre-program operation mode does not perform a re-program operation procedure for the pre-programmed data. The pre-program manager 1130 can generate digest data indicating the state of the pre-programmed memory cells after the data is programmed in the pre-program operation mode. The digest data is then stored in a digest memory that is separately provided.

When a read request for the pre-programmed data is received from the host 100, the pre-program manager 1130 can read the pre-program operation data from the non-volatile memory device 1300 and perform a recovery read operation using the digest data. In addition, the pre-program manager 1130 may perform re-programming on the pre-programmed data to secure the capacity of the digest memory when the digest memory is insufficient. In other words, after performing re-programming based on the digest data stored in the digest memory, the pre-program manager 1130 may invalidate the digest data from the digest memory. In some implementations, the pre-program manager 1130 may perform migration on the pre-programmed data when the digest memory is insufficient. That is, the pre-programmed data stored in the pre-program block may be moved to the general user block based on the digest data stored in the digest memory. Thereafter, the pre-program manager 1130 may deallocate or invalidate the digest data. The memory capacity of the invalidated digest data may be returned to the digest memory.

In addition, when a write request is received from the host 100, the pre-program manager 1130 can set the non-volatile memory device 1300 to the pre-program operation mode or the normal program mode according to the memory capacity of the digest memory. When the capacity of the digest memory is sufficient, the pre-program manager 1130 can set the program mode of the non-volatile memory device 1300 to the pre-program operation mode. On the other hand, when the capacity of the digest memory is not sufficient, the pre-program manager 1130 can set the program mode of the non-volatile memory device 1300 to the normal program mode.

The storage controller 1100 can advance the transmission of a complete message for a write request by the pre-program manager 1130. For example, the storage controller 1100 can transmit the complete message to the host 100 at the time when the pre-program operation of the write-requested data and the program of the digest data are completed. In some implementations, the storage controller 1100 may transmit the complete message to the host 100 when the pre-program operation of the write-requested data and the generation of the digest data are completed. In this way, the complete message can be transmitted for the write request of the host 100 without performing the re-program operation, thereby improving the write performance perceived by the host 100. In addition, since the operation for the read request is completed without performing the re-program operation, the power required for the re-program operation can be reduced. The functions or features of the pre-program manager 1130 will be described in more detail through the drawings described below.

The non-volatile memory device 1300 stores data or outputs stored data under the control of the storage controller 1100. In particular, the non-volatile memory device 1300 of the present disclosure is set to the pre-program operation mode or the normal program mode in response to a program mode setting command of the storage controller 1100. If set to the pre-program operation mode from the storage controller 1100, the non-volatile memory device 1300 programs the data requested to be written into a pre-program block. At this time, digest data or state group data (hereinafter, SGD) indicating the state information of the pre-programmed data are generated. Afterwards, if the capacity of the digest memory is insufficient, the storage controller 1100 will read the digest data and the pre-programmed data and perform re-program operation. If set to the normal program mode from the storage controller 1100, the non-volatile memory device 1300 performs a general data write operation that does not require the generation of digest data.

Each of the storage controller 1100 and the non-volatile memory device 1300 constituting the storage device 1000 may be provided as one chip, one package, or one module. Alternatively, the storage controller 1100 and the non-volatile memory device 1300 may be formed as one chip, one package, or one module, and provided as a memory system such as a memory card, a memory stick, a solid state drive SSD, etc.

The storage device 1000 of the present disclosure described above performs the pre-program operation without re-programming data requested to be written in the pre-program operation mode. Therefore, the write performance and power efficiency of the storage device 1000 of the present disclosure can be improved by skipping the re-program operation.

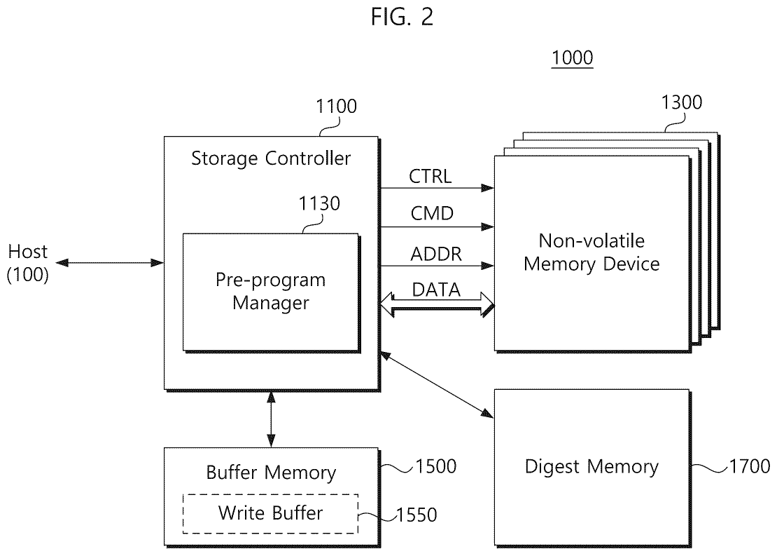

FIG. 2 is a block diagram showing an example of a storage device. Referring to FIG. 2, the storage device 1000 may include a storage controller 1100, a non-volatile memory device 1300, a buffer memory 1500, and a digest memory 1700.

The storage controller 1100 may be configured to control the non-volatile memory device 1300 and the buffer memory 1500 according to a command or control from a host 100. For example, the storage controller 1100 may write data to the non-volatile memory device 1300 or read data stored in the non-volatile memory device 1300 according to a request from the host 100. In order to access the non-volatile memory device 1300, the storage controller 1100 can provide a command CMD, an address ADDR, data DATA, and a control signal CTRL to the non-volatile memory device 1300.

The storage controller 1100 can set the non-volatile memory device 1300 to a pre-program operation mode or a normal program mode in response to a write request or a read request from the host 100. The storage controller 1100 can provide a command for setting the non-volatile memory device 1300 to the pre-program operation mode. That is, the storage controller 1100 can provide a pre-program operation mode setting command for setting the write mode to the pre-program operation mode to the non-volatile memory device 1300.

When write data is input from the host 100, the storage controller 1100 stores the write data in a write buffer 1550 allocated to the buffer memory 1500. Then, the write data is programmed in a pre-program block of a non-volatile memory device 1300 while buffered in the write buffer 1550. Then, the storage controller 1100 will generate digest data of the pre-programmed data and store the digest data in the digest memory 1700. When storing the digest data is completed, the write data stored in the write buffer 1550 is invalidated or deallocated. Then, a complete message for the write request will be transmitted to the host 100. To execute the pre-program operation, the storage controller 1100 may include a pre-program manager 1130. The pre-program manager 1130 may be implemented in hardware or software. Alternatively, the pre-program manager 1130 may be provided in the form of firmware, which is a hybrid of hardware and software.

When the write request is received in the pre-program operation mode, the pre-program manager 1130 may determine whether to continue the pre-program operation mode according to the state of the digest memory 1700. For example, when the write request is received, the pre-program manager 1130 checks the available memory capacity of the digest memory 1700. If the available memory capacity of the digest memory 1700 is greater than a threshold value, the pre-program manager 1130 maintains the program mode of the non-volatile memory device 1300 in the pre-program operation mode. Then, the pre-program manager 1130 programs the write-requested data into the pre-program block of the non-volatile memory device 1300. Then, the pre-program manager 1130 generates digest data corresponding to the pre-programmed data. The generated digest data will be stored in the digest memory 1700.

On the other hand, if the available memory capacity of the digest memory 1700 is smaller than the threshold, the pre-program manager 1130 changes the program mode of the non-volatile memory device 1300 to the normal program mode. Then, the data requested to be written is stored in the non-volatile memory device 1300 in the normal program mode, not the pre-program operation mode. In some implementations, the pre-program manager 1130 may execute the re-program operation for the data existing in the pre-program block in order to process the data requested to be written in the pre-program operation mode. For the re-program operation, the digest data stored in the digest memory 1700 is used. The digest data used for the re-program operation may be invalidated in the digest memory 1700. Therefore, the available memory capacity of the digest memory 1700 can be secured by executing the re-program operation. According to the capacity of the digest memory 1700, the pre-program manager 1130 can program the write-requested data into the non-volatile memory device 1300 in the pre-program operation mode.

In some implementations, the pre-program manager 1130 can apply migration to data existing in the pre-program block in order to process the write-requested data in the pre-program operation mode. That is, the pre-programmed data moves from the pre-program block to the general memory block through migration. For the migration of the pre-programmed data, the digest data stored in the digest memory 1700 is used. When the pre-programmed data is read, a recovery read operation using the digest data is applied. And the multi-page data restored by the recovery read will be programmed into the general memory block. The digest data used for the recovery read operation is deallocated from the digest memory 1700. Therefore, the available memory capacity of the digest memory 1700 can be secured through migration. According to the capacity of the digest memory 1700, the pre-program manager 1130 can program the data requested to be written in the pre-program operation mode to the non-volatile memory device 1300.

The non-volatile memory device 1300 can store data received from the storage controller 1100 or transmit the stored data to the storage controller 1100. The non-volatile memory device 1300 is provided as a storage medium of the storage device 1000. For example, the non-volatile memory device 1300 can be provided as a NAND flash memory having a large storage capacity. The non-volatile memory device 1300 can include a plurality of flash memory devices. In particular, the non-volatile memory device 1300 can include a pre-program block that stores data in the pre-program operation mode. When set to the pre-program operation mode by the storage controller 1100, the non-volatile memory device 1300 writes the write data to the pre-program block according to the pre-program operation procedure. On the other hand, when the pre-program operation mode is released, the non-volatile memory device 1300 programs the write data to the general memory block according to the normal program procedure that does not consider the digest data.

The buffer memory 1500 can be used as a data buffer for data exchange between the storage device 1000 and the host 100. The buffer memory 1500 can include a write buffer 1550 in which write data provided from the host 100 is temporarily stored. When data existing in the non-volatile memory device 1300 is cached at the time of a read request from the host 100, the buffer memory 1500 can also support a cache function that directly provides the cached data to the host. The buffer memory 1500 may be provided as a synchronous DRAM to provide sufficient buffering in a storage device 1000 used as a large-capacity auxiliary memory device. However, it is obvious to those skilled in the art that the buffer memory 1500 is not limited to the disclosure herein.

The digest memory 1700 stores digest data having state information or hint information of pre-programmed data. The pre-programmed data may be divided into state groups that do not overlap each other. The hint information indicating which state group the programmed data belongs to is the digest data. Therefore, if there is only the pre-programmed data and the digest data, data recovery read operation is possible. The digest memory 1700 for storing the digest data may be implemented in various ways. For example, the digest memory 1700 may be implemented as a volatile memory such as a DRAM or a non-volatile memory such as a resistive memory (e.g., RRAM or PRAM). Alternatively, the digest memory 1700 may be configured on the buffer memory 1500 or may be implemented by borrowing a portion of the non-volatile memory device 1300.

According to the above description, the storage controller 1100 can perform the pre-program operation without the re-program procedure for the data requested to be written. Accordingly, the write performance degradation and power consumption of the storage device 1000 caused by the re-program operation can be reduced.

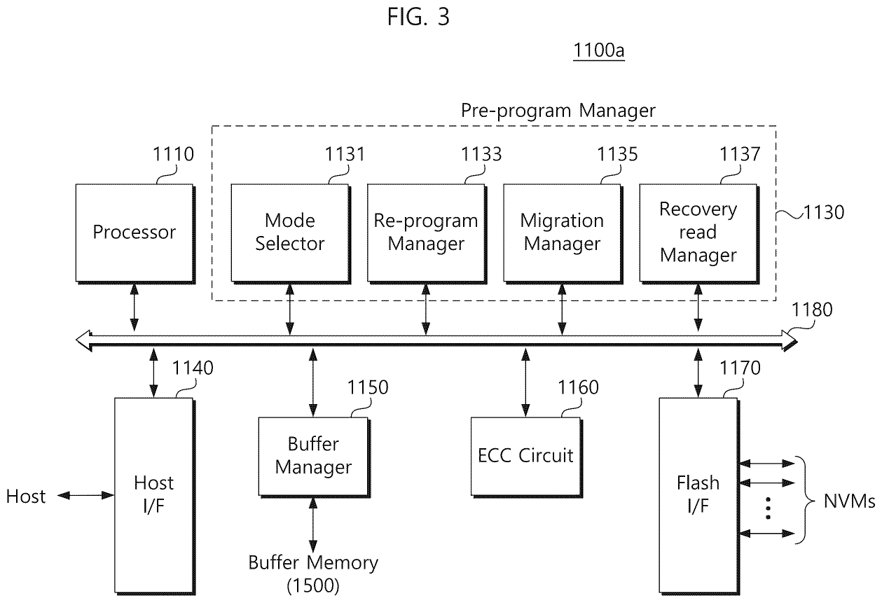

FIG. 3 is a block diagram showing an example of the storage controller of FIG. 2. Referring to FIG. 3, the storage controller 1100a of the present disclosure may include a processor 1110, a pre-program manager 1130, a host interface 1140, a buffer manager 1150, an error correction code (hereinafter, ECC) circuit 1160, a flash interface 1170, and a system bus 1180.

The processor 1110 may include a processing unit such as a central processing unit CPU or a microprocessor. The processor 1110 controls all operations of the storage controller 1100a. The processor 1110 may execute software or firmware for driving the storage controller 1100a. The processor 1110 may execute, for example, various firmware loaded into a code memory. In some implementations, the processor 1110 may execute the pre-program manager 1130 of the present disclosure when the pre-program manager 1130 is provided as a software module.

The pre-program manager 1130 performs a pre-program operation of the present disclosure in response to a write request from the host 100. To this end, the pre-program manager 1130 may include a mode selector 1131, a re-program manager 1133, a migration manager 1135, and a recovery read manager 1137. The mode selector 1131 may select a program mode of the non-volatile memory device 1300 according to an available memory capacity of the digest memory 1700 when the write request is received from the host 100. That is, the mode selector 1131 maintains the program mode of the non-volatile memory device 1300 in the pre-program operation mode when the available memory capacity of the digest memory 1700 is greater than or equal to a threshold. On the other hand, the mode selector 1131 can change the program mode of the non-volatile memory device 1300 to the normal program mode or trigger a re-program operation or migration operation when the available memory capacity of the digest memory 1700 is less than the threshold.

The re-program manager 1133 is activated when the available memory capacity of the digest memory 1700 is less than the threshold. When the re-program manager 1133 is activated, the re-program operation for already pre-programmed data can be performed. The re-program manager 1133 performs the re-program operation for pre-programmed memory cells based on the digest data stored in the digest memory 1700. A re-program operation is an operation that programs pre-programmed memory cells in an incomplete program state to a completed program state using the digest data. When the re-program operation is completed, the re-program manager 1133 can invalidate or deallocate the corresponding digest data stored in the digest memory 1700. Therefore, after the re-program operation is completed, the write-requested data can be programmed into the non-volatile memory device 1300 according to the pre-program operation mode and the digest data can be stored in the digest memory 1700. That is, the re-program manager 1133 of the present disclosure can be activated when the available memory capacity of the digest memory 1700 is insufficient.

The migration manager 1135, like the re-program manager 1133, can also be activated when the available memory capacity of the digest memory 1700 is less than a threshold. However, if the available memory capacity of the digest memory 1700 is less than the threshold, only one of the re-program manager 1133 and the migration manager 1135 can be activated. If the available memory capacity of the digest memory 1700 is insufficient, the migration manager 1135 performs migration on the already pre-programmed data. That is, the migration manager 1135 moves the pre-programmed data to a general memory block based on the digest data stored in the digest memory 1700. Then, the migration manager 1135 deallocates or invalidates the digest data corresponding to the moved data from the digest memory 1700. The pre-programming of the write-requested data becomes possible by the available memory capacity secured by deallocating the digest memory 1700.

The recovery read manager 1137 performs a read operation on the pre-programmed data. When the read request of pre-programmed data is received from the host 100, the recovery read manager 1137 reads the corresponding digest data stored in the digest memory 1700. Then, using the digest data, the recovery read manager 1137 performs the recovery read operation on the data of the pre-program block of the non-volatile memory device 1300. The read data will be provided to the host 100. The digest data used by the recovery read operation can be deallocated from the digest memory 1700.

The host interface 1140 provides an interface between the host and the storage controller 1100. The host 100 and the storage controller 1100a can be connected through one of various standardized interfaces. Here, the standard interfaces include various interface methods such as Advanced Technology Attachment (ATA), Serial ATA (SATA), external SATA (e-SATA), Small Computer Small Interface (SCSI), Serial Attached SCSI (SAS), Peripheral component Interconnection (PCI), PCIe (PCI Express), Universal Serial Bus (USB), IEEE 1394, Universal Flash Storage (UFS), Card interface, etc.

The buffer manager 1150 controls read and write operations of the buffer memory 1500. For example, the buffer manager 1150 temporarily stores write data or read data in the buffer memory 1500 under the control of the processor 1110 or the pre-program manager 1130. For example, the buffer manager 1150 can temporarily store the generated digest data in the buffer memory 1500 when the pre-program operation is completed. The buffer manager 1150 receives and processes read or write requests to the buffer memory 1500.

The ECC circuit 1160 performs error correction encoding on data programmed in the non-volatile memory device 1300. That is, the ECC circuit 1160 encodes the programmed data to generate ECC parity. The ECC circuit 1160 performs decoding for error detection and correction on the read data. Error detection or error correction is performed using ECC parity included in the read data.

The flash interface 1170 provides interfacing between the storage controller 1100a and the non-volatile memory device 1300. For example, data processed by the processor 1110 is stored in the non-volatile memory device 1300 through the flash interface 1170.

An implementation of the configurations of the storage controller 1100a has been described above. The storage controller 1100a of the present disclosure can perform the pre-program operation without the re-program operation procedure for write-requested data. In addition, the storage controller 1100a can maintain or change the pre-program operation mode according to the available memory capacity of the digest memory 1700. By applying the pre-program operation mode of the present disclosure, the write performance degradation of the storage device 1000 due to the re-program operation can be reduced. In addition, power consumption can be reduced by reducing the number of occurrences of the re-program operation.

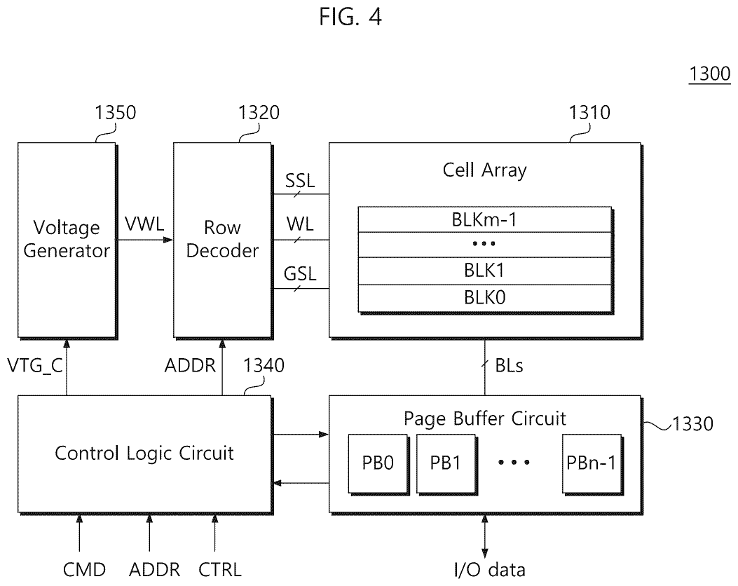

FIG. 4 is an exemplary block diagram of the non-volatile memory device of FIG. 2. Referring to FIG. 4, the non-volatile memory device 1300 may include a cell array 1310, a row decoder 1320, a page buffer circuit 1330, a control logic circuit 1340, and a voltage generator 1350. Although not shown in FIG. 4, the non-volatile memory device 1300 may further include a data input/output circuit or an input/output interface. In addition, the non-volatile memory device 1300 may further include elements such as a column logic, a pre-decoder, a temperature sensor, a command decoder, and an address decoder.

The cell array 1310 may include a plurality of memory blocks BLK0 to BLKm−1 (m is a positive integer). Each of the plurality of memory blocks BLK0 to BLKm−1 may include a plurality of memory cells. A plurality of memory blocks BLK0 to BLKm−1 may be included in one memory plane, but the present disclosure is not limited thereto. The cell array 1310 may be connected to the page buffer circuit 1330 through bit line BL and may be connected to a row decoder 1320 through word line WL, string select lines SSL, and ground select lines GSL.

The row decoder 1320 may select one of the memory blocks of the cell array 1310 in response to an address ADDR. The row decoder 1320 may select one of the word lines of the selected memory block in response to the address ADDR. The row decoder 1320 transmits a word line voltage VWL corresponding to an operation mode to a word line of the selected memory block. During a program operation, the row decoder 1320 transmits a program voltage and a verification voltage to the selected word line, and a pass voltage to the non-selected word line. During a read operation, the row decoder 1320 transmits a read voltage to the selected word line, and a read pass voltage to the non-selected word line.

The page buffer circuit 1330 may include a plurality of page buffers PB0 to PBn−1. The plurality of page buffers PB0 to PBn−1 may be respectively connected to memory cells through a plurality of bit lines BLs. The page buffer circuit 1330 may select at least one bit line among the bit lines BLs in response to a column address. The page buffer circuit 1330 may operate as a write driver or a sense amplifier depending on the operation mode. For example, during the program operation, the page buffer circuit 1330 may apply a bit line voltage corresponding to data to be programmed to the selected bit line. During the read operation, the page buffer circuit 1330 can detect the current or voltage of the selected bit line to detect data stored in the memory cell.

The control logic circuit 1340 can generally control various operations within the non-volatile memory device 1300. The control logic circuit 1340 can output various control signals for programming data in the cell array 1310, reading data from the cell array 1310, or erasing data stored in the cell array 1310 in response to a control signal CTRL, a command CMD, and/or an address ADDR. For example, the control logic circuit 1340 can output a voltage control signal VTG_C, an address ADDR, etc.

In some implementations, the control logic circuit 1340 can output control signals for programming multi-bit data according to the received control signal CTRL, the command CMD, and/or the address ADDR. For example, the control logic circuit 1340 may output control signals for the pre-program operation and re-program operation, or may output control signals for reading out pre-programmed multi-page data. In particular, the control logic circuit 1340 may perform the program mode in the pre-program operation mode according to a pre-program operation mode setting command from the storage controller 1100. That is, when the control logic circuit 1340 is set to the pre-program operation mode, the control logic circuit 1340 programs the write data into the pre-program block.

The voltage generator 1350 may generate various types of voltages for performing program, read, and erase operations based on the voltage control signal VTG_C. For example, the voltage generator 1350 may generate the program voltage, the read voltage, a program verification voltage as a word line voltage VWL. For example, the program voltage may be generated in an incremental step pulse program ISPP manner.

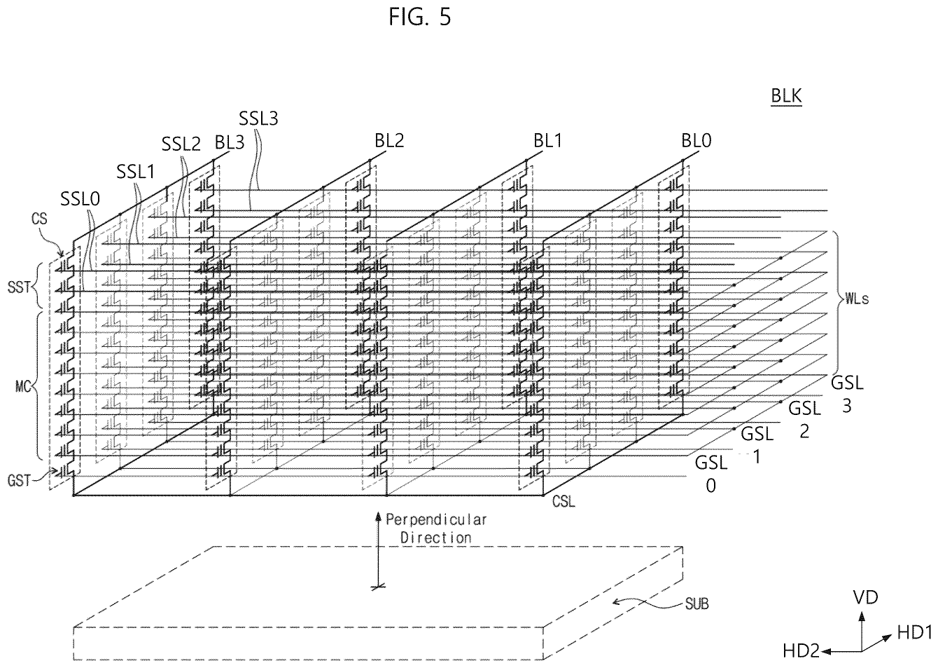

FIG. 5 is a circuit diagram showing an exemplary structure of a memory block constituting the cell array of FIG. 4. Referring to FIG. 5, cell strings CS are formed between bit lines BL0, BL1, BL2, and BL3 and a common source line CSL to form a memory block BLK.

A plurality of cell strings are formed between the bit line BL0 and the common source line CSL. The string selection transistor SST of the cell strings CS are connected to the corresponding bit line BL. The ground selection transistor GST of the cell strings CS are connected to the common source line CSL. Memory cells MCs are provided between the string selection transistor SST and the ground selection transistor GST of the cell strings CS.

Each of the cell strings CS includes the ground selection transistor GST. The ground selection transistor included in the cell strings CS can be controlled by the ground selection line GSL. Although not shown, the cell strings corresponding to each row can be controlled by different ground selection lines.

In the above, the circuit structure of the memory cells included in one memory block BLK has been briefly described. However, the circuit structure of the illustrated memory block is a simplified structure for the convenience of explanation, and the actual memory block is not limited to the illustrated example. That is, it will be well understood that one physical block can include more semiconductor layers, bit lines BLs, and string selection lines SSLs.

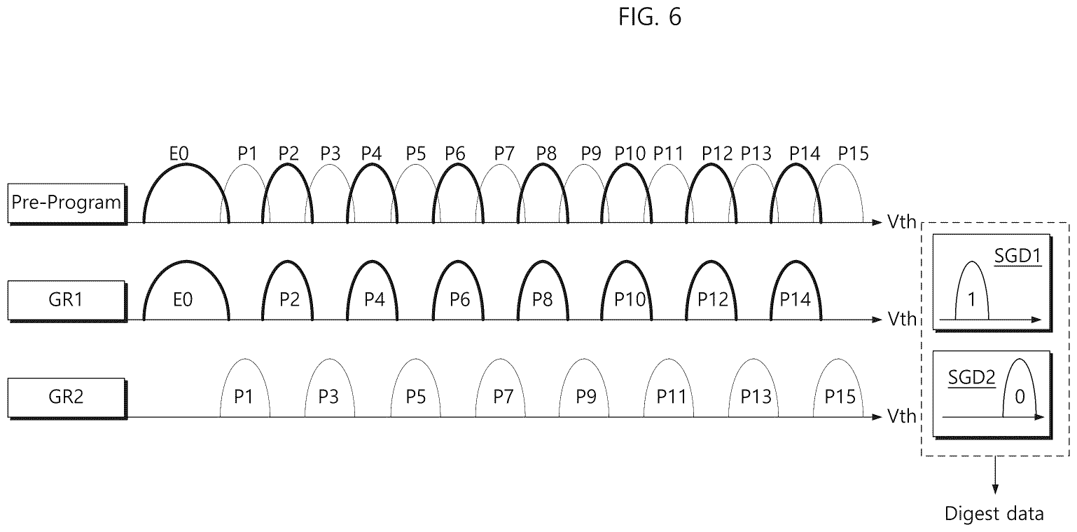

FIG. 6 is an example drawing showing the data state and digest data of a memory cell according to the pre-program operation of the present disclosure. Referring to FIG. 6, when a program is started, the storage device 1000 can program multi-bit data in a pre-program block of a non-volatile memory device 1300 in a pre-program operation mode. Then, digest data corresponding to the pre-programmed data is generated.

When the multi-bit data is 4-bit data, as illustrated, the pre-programmed memory cell can have a threshold voltage corresponding to one of 16 threshold voltage states (E0, P1 to P15). The 16 threshold voltage states can each correspond to 16 values that the multi-bit data can have. That is, the pre-programmed memory cell can correspond to one of the 16 threshold voltage states according to the multi-bit data value. In this case, the threshold voltages of the memory cells may vary due to the capacitive coupling between adjacent memory cells, and the width of each threshold voltage distribution may be widened due to this threshold voltage variation. Accordingly, adjacent threshold voltage distributions may overlap.

The threshold voltage distributions of the pre-programmed memory cells may be divided into a plurality of state groups. For example, the threshold voltage states corresponding to the erase state E0 and the program states P1 to P15 may be divided into a first state group GR1 and a second state group GR2. In some implementations, each of the state groups may include different threshold voltage distributions, and the threshold voltage distributions of each of the state groups may not overlap each other. For example, the first state group GR1 may include threshold voltage distributions corresponding to the erase state E0, the second program state P2, the fourth program state P4, the sixth program state P6, the eighth program state P8, the tenth program state P10, the twelfth program state P12, and the fourteenth program state P14. And the second state group GR2 may include threshold voltage states corresponding to the first program state P1, the third program state P3, the fifth program state P5, the seventh program state P7, the ninth program state P9, the eleventh program state P11, the thirteenth program state P13, and the fifteenth program state P15.

Each of the state groups may be represented by state group data. For example, the first state group GR1 and the second state group GR2 can be represented by 1-bit state group data SGD1. For example, the state group data SGD1 indicating the first state group GR1 can be represented as ‘1’, and the state group data SGD2 indicating the second state group GR2 can be represented as ‘0’. However, the present disclosure is not limited thereto, and the number of bits of the state group data can vary depending on the number of state groups. For example, when the threshold voltage distributions are divided into four state groups, the state group data can be 2-bit data. In this case, the number of bits of the state group data can be smaller than the number of bits of the multi-bit data, and when the multi-bit data is N bits, the state group data can be N−1 bits.

The pre-programmed multi-bit data can correspond to the state group data indicating one of the plurality of state groups according to the data value. For example, the multi-bit data corresponding to the erase state E0 may correspond to the state group data SGD1 indicating the first state group GR1, and the multi-bit data corresponding to the first program state P1 may correspond to the state group data SGD2 indicating the second state group GR2. The state group data SGD1 and SGD2 may be used as hint data for restoring read of the pre-programmed multi-bit data. That is, the state group data SGD1 and SGD2 correspond to the digest data of the pre-programmed multi-bit data.

The storage device 1000 may restore the multi-bit data based on the digest data. For example, the storage device 1000 may read the multi-bit data from the pre-programmed memory cell based on the digest data. As illustrated, even if there is an overlapping region in the threshold voltage distributions of pre-programmed memory cells, a read operation can be performed for each state group based on the digest data. In this case, it can be distinguished to which threshold voltage distribution the overlapping region belongs. Ultimately, if only the digest data is acquired, reading of the pre-programmed multi-bit data is possible.

As described above, the storage device 1000 can perform the pre-program operation without a re-programming procedure for the data requested to be written. A write request for data can be completed with the pre-program operation and digest data program. Therefore, the write performance degradation and power consumption of the storage device 1000 caused by the re-program operation can be reduced.

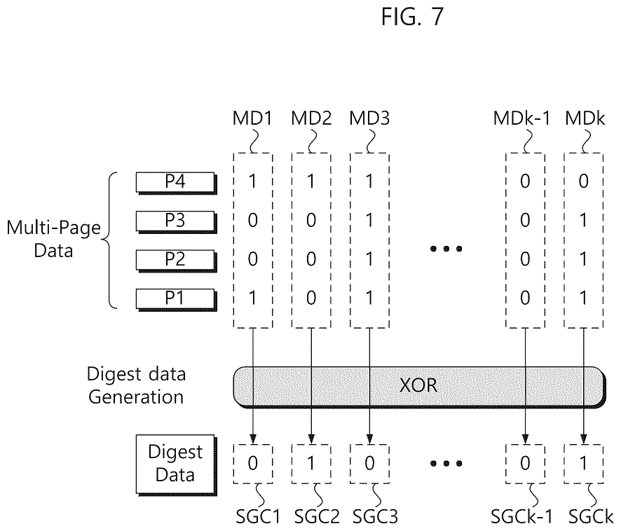

FIG. 7 is a drawing exemplarily showing a method of generating digest data according to one implementation of the present disclosure. Referring to FIG. 7, the multi-bit data can include first to k-th multi-bit data MD1 to MDk to be programmed into k memory cells connected to one word line. For example, if the multi-bit data is 4-bit data, the multi-page data may include the first to fourth page data PD1 to PD4.

The digest data may include state group codes SGC1 to SGCk generated based on the multi-bit data MD1 to MDk. For example, the state group code SGC may be generated based on the number of logical ‘1’ (or ‘0’) bits of the multi-bit data. For example, in the case of the multi-bit data MD2 having an odd number of logical ‘1’s, the state group code SGC2 corresponding to ‘1000’ may be generated as ‘1’. And in the case of the multi-bit data MD1 having an even number of logical ‘1’s, the state group code SGC1 corresponding to ‘1001’ may be generated as ‘0’. That is, each of the state group codes SGC1 to SGCk can be generated through an exclusive OR (XOR) operation of the logical bits of each of the corresponding multi-bit data MD1 to MDk.

The bits of each of the generated state group codes SGC1 to SGCk are combined into digest data having the length of one page data. The generated digest data may be less than the bits of the multi-page data. For example, when 1-bit state group data is generated from 4-bit multi-data, the bits of the state group code may be reduced by ¼ times compared to the bits of the multi-page data.

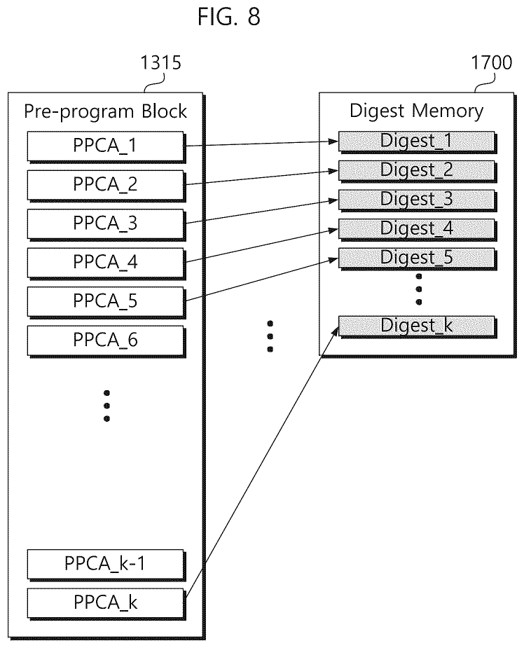

FIG. 8 shows an example relationship between the pre-program block and the digest memory according to the pre-program operation of the present disclosure. Referring to FIG. 8, multi-page data is programmed in the pre-program cell areas PPCA_1 to PPCA_k of the pre-program block 1315 of the non-volatile memory device 1300. And digest data Digest_1˜Digest_k can be generated from each of the pre-programmed multi-page data in each of the pre-program cell areas PPCA_1˜PPCA_k.

Multi-page data is programmed in the pre-program cell areas PPCA_1 to PPCA_k of the pre-program block 1315. For example, each of the pre-program cell areas PPCA_1 to PPCA_k can have four pages of write data programmed. Then, digest data Digest_1 of one page can be generated from the pre-programmed multi-page data in the pre-program cell area PPCA_1. Similarly, digest data Digest_2 of one page can be generated from the pre-programmed multi-page data in the pre-program cell area PPCA_2. If digest data is generated in this way, the pre-programmed data and digest data can be managed at a memory capacity ratio of 4:1.

According to the pre-program operation mode of the present disclosure, the data requested to be written can be programmed at high speed in the pre-program block 1315 of the non-volatile memory device 1300. Then, digest data corresponding to the pre-programmed data is generated and stored in the digest memory 1700. No additional re-program operation for the pre-programmed data occurs.

When the read request for the pre-programmed data stored in the pre-program block 1315 is received, a recovery read of the pre-programmed data can be performed based on the digest data stored in the digest memory 1700. Therefore, a highly reliable read operation is possible without the re-program operation.

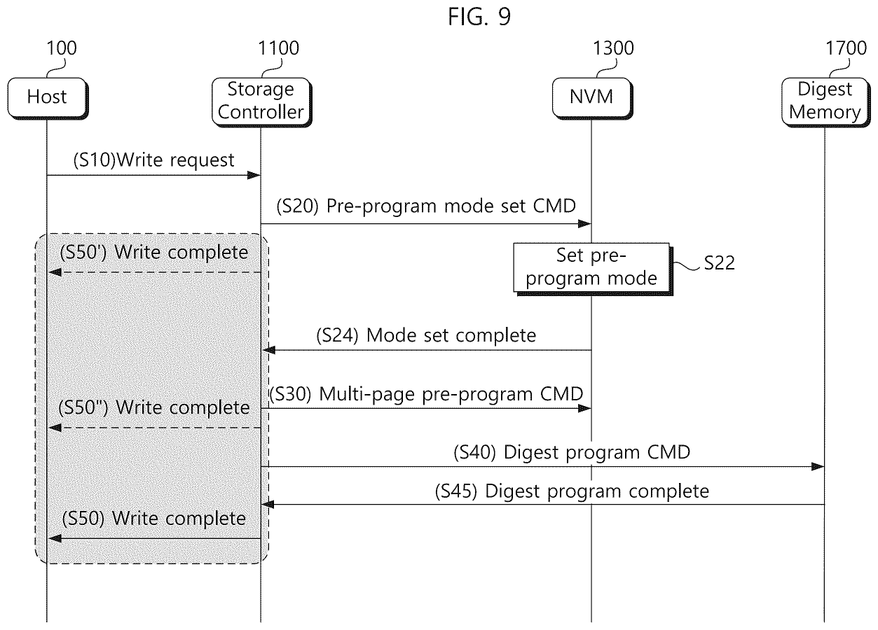

FIG. 9 is a drawing showing an example of the operation of a storage device during a pre-program operation. Referring to FIG. 9, when a write request from a host 100 is transmitted to a storage device 1000, the pre-program operation of the present disclosure begins. Here, it is assumed that the storage device 1000 is not initially set to a pre-program operation mode.

In step S10, the host 100 transmits a write request to the storage device 1000. Then, the storage controller 1100 of the storage device 1000 receives the write request.

In step S20, the storage controller 1100 transmits a pre-program operation mode set command to the non-volatile memory device 1300. Through the pre-program operation mode set command, the non-volatile memory device 1300 can maintain data in a pre-programmed state without re-programming.

In step S22, the non-volatile memory device 1300 may select a pre-program block as a target block of write data in response to the pre-program operation mode setting command. Alternatively, the non-volatile memory device 1300 may program write data to be written to the selected memory block in the pre-program operation mode according to the pre-program operation mode setting command.

In step S24, the non-volatile memory device 1300 transmits a mode setting completion message indicating that the mode setting according to the pre-program operation mode setting command has been completed to the storage controller 1100.

In step S30, the storage controller 1100 transmits a pre-program operation command to the non-volatile memory device 1300 to program the multi-page data requested to be written from the host 100. In response to the pre-program operation command, the non-volatile memory device 1300 will program the multi-page data in the pre-program operation mode without re-programming.

In step S40, the storage controller 1100 can generate digest data of pre-programmed multi-page data. And the storage controller 1100 will transmit the program command of the generated digest data to the digest memory 1700. The digest memory 1700 stores the received digest data in the designated digest memory area.

In step S45, the digest memory 1700 can transmit a digest program completion signal to the storage controller 1100 when the program of the write requested digest data is completed.

In step S50, the storage controller 1100 transmits a write complete message to the host 100 to notify the completion of the write request. The issue time of the write complete message can be immediately after the program of the digest data is completed. That is, the issue time of the write complete message can be transmitted to the host 100 regardless of whether the re-program operation in the non-volatile memory device 1300 is completed. Therefore, the program throughput of the storage device 1000 observed from the host 100 can be improved.

Here, the issue timing of the write complete message can be changed in various ways. For example, the issue timing of the write complete message can correspond immediately after the transmission of the pre-program operation mode setting command to the non-volatile memory device 1300. In some implementations, the issue timing of the write complete message may correspond immediately after the transmission of the multi-page pre-program operation command to the non-volatile memory device 1300. That is, according to the pre-program operation of the present disclosure, the storage device 1000 can significantly reduce the time from the time of receiving the write request to the issue timing of the write complete message.

According to the pre-program operation of the present disclosure, the program throughput of the storage device 1000 can be improved. In addition, since the write buffer (1550, see FIG. 2) can be deallocated after the pre-program operation, it is also possible to save write buffer resources. In addition, since the operation can be completed without the re-programming procedure for the write request of the host 100, the power consumption required for the re-programming can also be reduced.

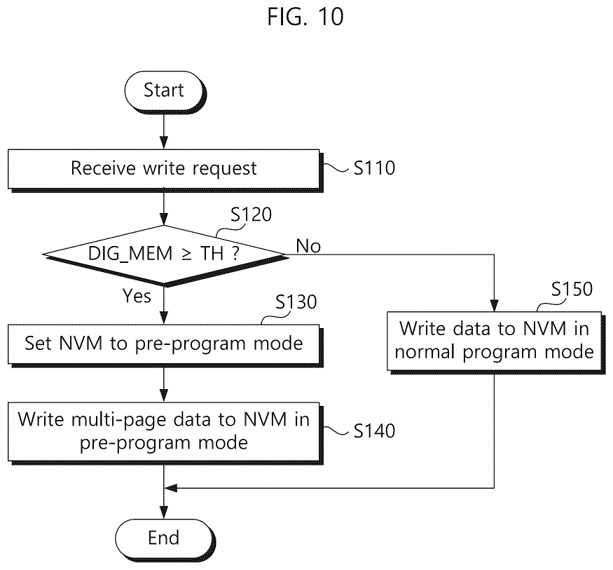

FIG. 10 is a flowchart showing an example of the control operation of the storage controller for the pre-program operation of the present disclosure. Referring to FIG. 10, the storage controller (1100, see FIG. 2) can dynamically change the program mode according to the available memory capacity DIG_MEM of the digest memory (1700, see FIG. 2).

In step S110, the storage controller 1100 receives a write request provided from the host 100.

In step S120, the storage controller 1100 determines whether the available memory capacity DIG_MEM of the digest memory 1700 is sufficient. That is, the storage controller 1100 checks whether the available memory capacity DIG_MEM of the digest memory 1700 is greater than or equal to the threshold value TH. If the available memory capacity DIG_MEM is greater than or equal to the threshold value TH (‘Yes’ direction), the procedure moves to step S130. On the other hand, if the available memory capacity DIG_MEM is less than the threshold value TH (‘No’ direction), the procedure moves to step S150.

In step S130, the storage controller 1100 sets the program mode of the non-volatile memory device 1300 to the pre-program operation mode. In other words, the storage controller 1100 can transmit a pre-program operation mode set command to the non-volatile memory device 1300. According to the pre-program operation mode set command, the non-volatile memory device 1300 maintains the pre-programmed data without re-programming.

In step S140, the storage controller 1100 transmits a pre-program operation command to the non-volatile memory device 1300 to program the multi-page data requested to be written from the host 100. According to the pre-program operation command, the non-volatile memory device 1300 will program the multi-page data in a pre-program operation mode without re-programming.

In step S150, the storage controller 1100 transmits a program command to the non-volatile memory device 1300 to program the data requested to be written from the host 100 in a normal program mode. According to the normal program mode, the non-volatile memory device 1300 can program the multi-page data requested to be written without generating digest data.

The storage controller 1100 can dynamically change the program mode of the data requested to be written according to the available memory capacity DIG_MEM of the digest memory 1700. Therefore, it is possible to provide flexible write performance according to the state of the digest memory 1700.

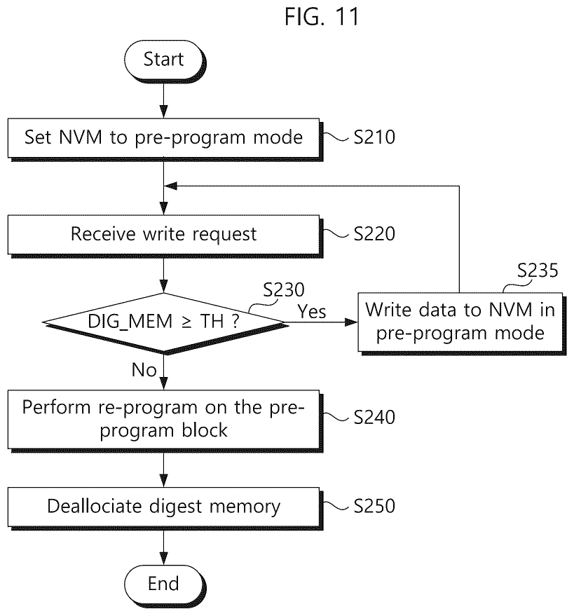

FIG. 11 is a flowchart showing an exemplary implementation for processing a write request received in a pre-program operation mode state. Referring to FIG. 11, a storage device (1000, see FIG. 2) can forcibly perform a re-program operation according to the available memory capacity DIG_MEM of a digest memory (1700, see FIG. 2) in a pre-program operation mode.

In step S210, the storage controller 1100 sets the program mode of the non-volatile memory device 1300 to the pre-program operation mode. The storage controller 1100 can set the non-volatile memory device 1300 to the pre-program operation mode using a pre-program operation mode set command. According to the pre-program operation mode set command, the non-volatile memory device 1300 will maintain the pre-programmed data without re-programming.

In step S220, the storage controller 1100 receives a write request provided from the

In step S230, the storage controller 1100 determines whether the available memory capacity DIG_MEM of the digest memory 1700 is sufficient. The storage controller 1100 checks whether the available memory capacity DIG_MEM of the digest memory 1700 is greater than or equal to a threshold value TH. If the available memory capacity DIG_MEM is greater than or equal to the threshold value TH (‘Yes’ direction), the procedure moves to step S235. On the other hand, if the available memory capacity DIG_MEM is less than the threshold value TH (‘No’ direction), the procedure moves to step S240.

In step S235, the storage controller 1100 programs the write-requested multi-page data into the non-volatile memory device 1300 in the pre-program operation mode. The non-volatile memory device 1300 is already set to the pre-program operation mode in step S210. Therefore, no additional mode setting command is required to program the write-requested multi-page data into pre-program mode. When the writing of the write-requested multi-page data is completed, the procedure returns to step S220 for receiving a new write request.

In step S240, the storage controller 1100 performs re-program operation of the pre-programmed data in the non-volatile memory device 1300. That is, before writing the write-requested data into the non-volatile memory device 1300, the re-programming of the already pre-programmed data is first performed. The digest data stored in the digest memory 1700 can be read for re-program operation. And the pre-programmed data will be re-programmed using the digest data.

In step S250, the digest data of the digest memory 1700 read for re-program operation can be deallocated from the digest memory 1700. That is, the digest data used for re-programming is invalidated, and the corresponding memory capacity is returned to the digest memory 1700. Therefore, the memory capacity of the digest memory 1700 can be secured. Thereafter, the storage controller 1100 can perform pre-program operation of the data requested to be written according to the securing of the available memory capacity DIG_MEM of the digest memory 1700.

The above has described an example of changing the program mode according to the available memory capacity DIG_MEM of the digest memory 1700. If the available memory capacity DIG_MEM of the digest memory 1700 is insufficient, the storage controller 1100 can forcibly perform re-program operation to secure the memory capacity.

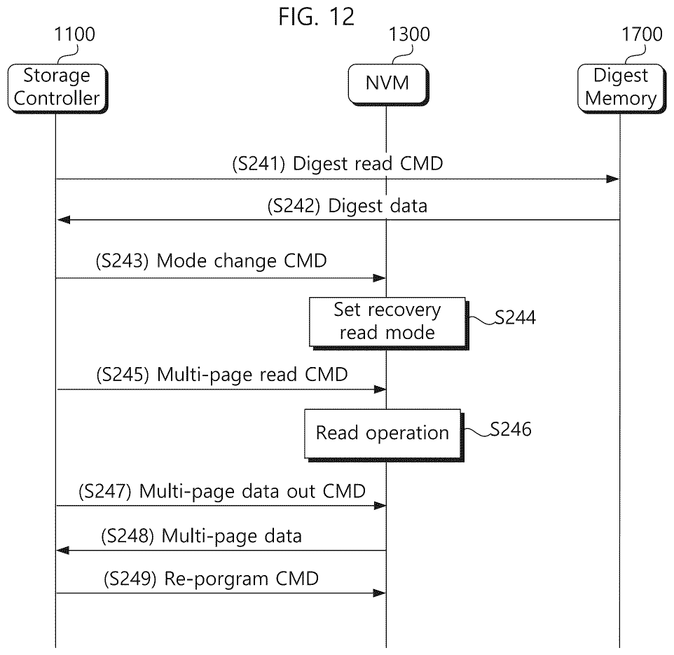

FIG. 12 is a drawing showing an example of the re-programming procedure of step S240 of FIG. 11 in more detail. Referring to FIG. 12, the storage controller (1100, see FIG. 2) can forcibly perform re-program operation when the available memory capacity DIG_MEM is insufficient in the pre-program operation mode state.

In step S241, the storage controller 1100 transmits a digest read command to the digest memory 1700. That is, the storage controller 1100 requests the digest memory 1700 to output digest data allocated to the data currently pre-programmed in the non-volatile memory device 1300.

In step S242, the digest memory 1700 outputs the digest data requested by the storage controller 1100.

In step S243, the storage controller 1100 transmits a mode change command to change the read mode of the non-volatile memory device 1300.

In step S244, the non-volatile memory device 1300 switches the data read mode to the recovery read mode. That is, the non-volatile memory device 1300 switches the operation mode from the pre-program operation mode to the recovery read mode.

In step S245, the storage controller 1100 transmits a multi-page read command. That is, the storage controller 1100 controls the non-volatile memory device 1300 to read the multi-page data stored in a pre-program block.

In step S246, the non-volatile memory device 1300 will sense the multi-page data requested to be read.

In step S247, the storage controller 1100 transmits a multi-page output command to the non-volatile memory device 1300.

In step S248, the non-volatile memory device 1300 transmits the sensed multi-page data to the storage controller 1100.

In step S249, the storage controller 1100 transmits a re-program operation command to the non-volatile memory device 1300 to perform re-program operation based on the output multi-page data and digest data.

In the above, the re-programming procedure performed when the available memory capacity of the digest memory 1700 is insufficient has been briefly described. However, each of the described steps is only an example, and the re-programming procedure may be changed in various ways.

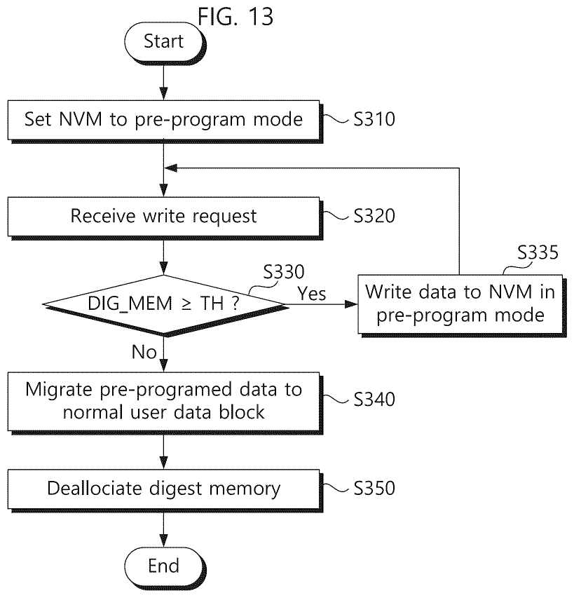

FIG. 13 is a flowchart showing an implementation for processing a write request received in a pre-program operation mode state. Referring to FIG. 13, the storage device (1000, see FIG. 2) may perform a migration operation according to the available memory capacity DIG_MEM of the digest memory (1700, see FIG. 2) in the pre-program operation mode state.

In step S310, the storage controller 1100 sets the program mode of the non-volatile memory device 1300 to the pre-program operation mode. The storage controller 1100 can set the non-volatile memory device 1300 using the pre-program operation mode set command. According to the pre-program operation mode set command, the non-volatile memory device 1300 will maintain the pre-programmed data without re-programming.

In step S320, the storage controller 1100 receives a write request provided from the

In step S330, the storage controller 1100 checks the available memory capacity DIG_MEM of the digest memory 1700. If the available memory capacity DIG_MEM is greater than or equal to the threshold value TH (‘Yes’ direction), the procedure moves to step S335. On the other hand, if the available memory capacity DIG_MEM is less than the threshold value TH (‘No’ direction), the procedure moves to step S340.

In step S335, the storage controller 1100 programs the write-requested multi-page data into the non-volatile memory device 1300 in the pre-program operation mode. The non-volatile memory device 1300 is already set to the pre-program operation mode In step S310. Therefore, an additional mode setting command for programming the write-requested multi-page data into the pre-program operation mode is unnecessary. When the writing of the write-requested multi-page data is completed, the procedure returns to step S320 for receiving a new write request.

In step S340, the storage controller 1100 performs migration on the data currently pre-programmed in the non-volatile memory device 1300. That is, migration of the already pre-programmed data is performed first before the programming of the write-requested data. Migration is an operation of reading the pre-programmed data in the pre-program block using digest data and moving it to the general user block.

In step S350, the digest data used for migration can be deallocated from the digest memory 1700. That is, the digest data used for migration is invalidated, and the corresponding memory capacity is returned to the digest memory 1700. Therefore, the memory capacity of the digest memory 1700 can be additionally secured. Thereafter, the storage controller 1100 can perform pre-programming of the write-requested data according to the securing of the available memory capacity DIG_MEM of the digest memory 1700.

The migration operation that can occur according to the available memory capacity DIG_MEM of the digest memory 1700 has been described above. If the available memory capacity DIG_MEM of the digest memory 1700 is insufficient, the storage controller 1100 can perform migration of the pre-programmed data to secure the memory capacity.

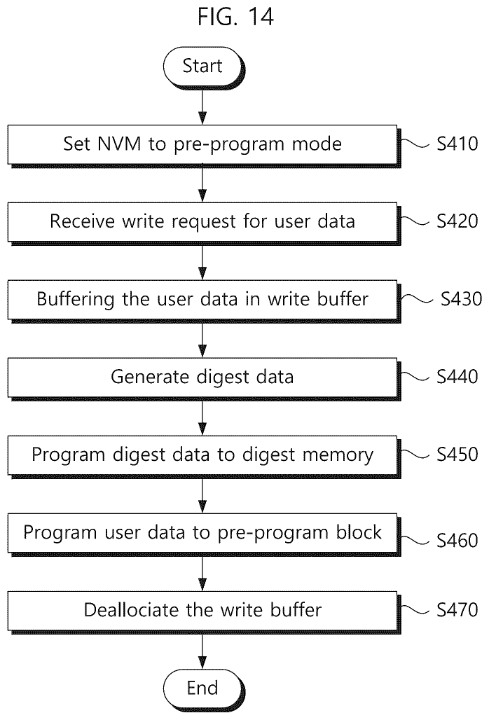

FIG. 14 is a flowchart briefly showing an example of a method of programming user data in a pre-program operation mode. Referring to FIG. 14, after the execution of the pre-program operation of the present disclosure, the write buffer 1550 can be deallocated without re-program operation.

In step S410, the storage controller 1100 sets the program mode of the non-volatile memory device 1300 to the pre-program operation mode. According to a pre-program operation mode setting command, the non-volatile memory device 1300 will maintain the pre-programmed data without re-program operation.

In step S420, the storage controller 1100 receives a write request of user data from the host 100.

In step S430, the storage controller 1100 stores the write-requested user data in the write buffer 1550 of the buffer memory 1500.

In step S440, the storage controller 1100 generates digest data based on the buffered user data. The digest data can be generated, for example, in the manner described in FIG. 7.

In step S450, the storage controller 1100 stores the generated digest data in the digest memory 1700.

In step S460, the storage controller 1100 programs the write-requested user data into the non-volatile memory device 1300 in a pre-program operation mode.

In step S470, the storage controller 1100 deallocates the user data allocated to the write buffer 1550. According to the deallocation of the user data from the write buffer 1550, the corresponding write buffer capacity is returned to the write buffer 1550. Accordingly, the memory capacity of the write buffer 1550 can be additionally secured.

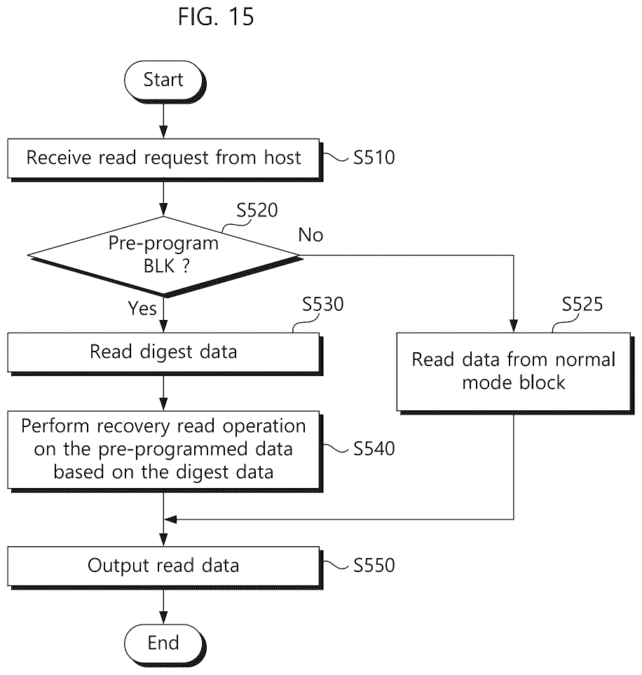

FIG. 15 is a flowchart showing an example of a method for processing a read request for pre-programmed data of the present disclosure. Referring to FIG. 15, when the read request for a pre-program block occurs, the storage controller (1100, see FIG. 2) can perform a recovery read operation using digest data.

In step S510, the storage controller 1100 receives a read request from the host 100.

In step S520, the storage controller 1100 checks whether the address of the read-requested data corresponds to the pre-program block. If the address of the read-requested data corresponds to the pre-program block (‘Yes’ direction), the procedure moves to step S530. On the other hand, if the address of the read-requested data does not correspond to the pre-program block (‘No’ direction), the procedure moves to step S525.

In step S525, the storage controller 1100 reads the read-requested data from the non-volatile memory device 1300 according to the general read mode.

In step S530, the storage controller 1100 transmits a digest read command to the digest memory 1700. The storage controller 1100 receives the digest data allocated to the read-requested pre-programmed data from the digest memory 1700.

In step S540, the storage controller 1100 performs a recovery read operation on the pre-programmed data. That is, the storage controller 1100 reads out the pre-programmed data using the digest data.

In step S550, the storage controller 1100 outputs the read data to the host 100 according to the recovery read mode or the general read mode.

The above is a brief description of the method for reading pre-programmed data of the present disclosure.

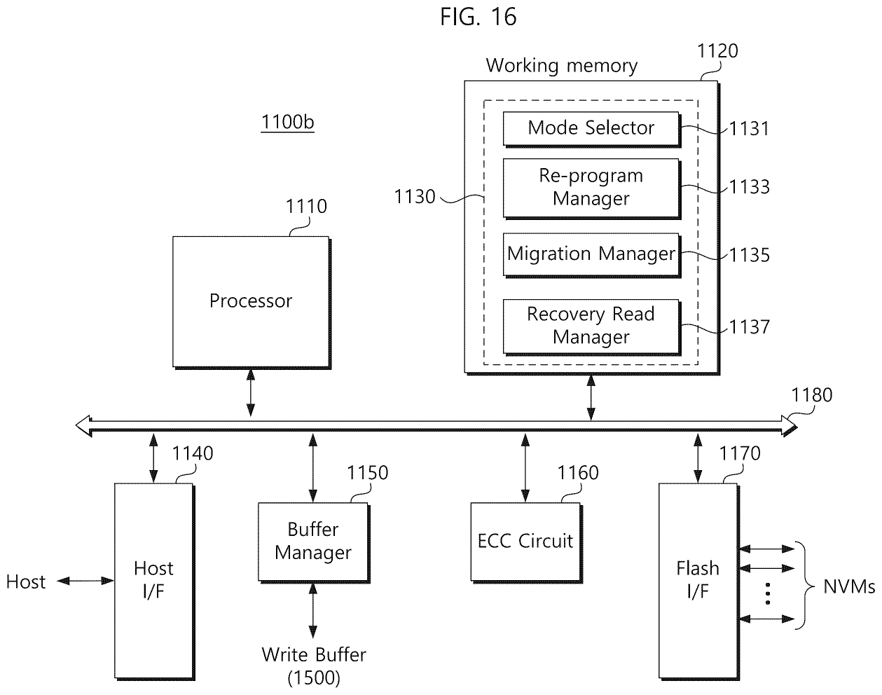

FIG. 16 is a block diagram showing an example of the storage controller of FIG. 2. Referring to FIG. 16, the storage controller 1100b of the present disclosure may include a processor 1110, a working memory 1120, a host interface 1140, a buffer manager 1150, an error correction code (hereinafter, ECC) circuit 1160, a flash interface 1170, and a system bus 1180. Here, the host interface 1140, the buffer manager 1150, the ECC circuit 1160, the flash interface 1170, and the system bus 1180 are substantially the same as those of FIG. 3. Therefore, a description of them will be omitted.

The processor 1110 may include a processing unit such as a central processing unit CPU or a microprocessor. The processor 1110 may execute software or firmware for driving the storage controller 1100b. The processor 1110 can execute a pre-program manager 1130 loaded into the working memory 1120.

A software module or data for controlling the storage controller 1100b is loaded into the working memory 1120. The software and data loaded into the working memory 1120 are driven or processed by the processor 1110. In particular, a pre-program manager 1130 in the form of software is loaded into the working memory 1120. The pre-program manager 1130 may include software modules such as a mode selector 1131, a re-program manager 1133, a migration manager 1135, and a recovery read manager 1137. The working memory 1120 may be implemented, for example, with SRAM. Each of the software modules may be driven by the processor 1110 to provide the functions of the mode selector 1131, the re-program manager 1133, the migration manager 1135, and the recovery read manager 1137 of FIG. 3.

An exemplary implementation of the configurations of the storage controller 1100b has been described above. According to the function of the storage controller 1100b of the present disclosure, the storage controller 1100b may perform the pre-program operation without a re-program operation procedure for the data requested to be written. In addition, the storage controller 1100b may maintain or change the pre-program operation mode according to the available memory capacity of the digest memory 1700. By applying the pre-program operation mode of the present disclosure, the write performance degradation of the storage device 1000 caused by the re-program operation may be blocked. In addition, the power consumption caused by the re-program operation may also be reduced as the number of occurrences of the re-program operation is reduced.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The above are specific implementations for carrying out the present disclosure. In addition to the above-described implementations, the present disclosure may include simple design changes or easily changeable implementations. In addition, the present disclosure will include techniques that can be easily modified and implemented using the implementations. Therefore, the scope of the present disclosure should not be limited to the above-described implementations, and should be defined by the claims and equivalents of the claims of the present disclosure as well as the claims to be described later.

What is claimed is:

1. A program method of a non-volatile memory device, comprising:
receiving a write request of multi-page data from a host;
comparing an available memory capacity of a digest memory with a threshold;
setting a write mode of the non-volatile memory device to a pre-program operation mode based on the available memory capacity being greater than or equal to the threshold; and
programming the multi-page data into a pre-program block of the non-volatile memory device.

2. The method of claim 1, comprising:
transmitting a completion message for the write request to the host after the multi-page data is programmed into the non-volatile memory device.

3. The method of claim 1, comprising:
generating digest data of the multi-page data; and
programming the digest data into the digest memory.

4. The method of claim 3, comprising:
transmitting a completion message for the write request to the host after the digest data is programmed in the digest memory.

5. The method of claim 3, comprising:
performing a re-program operation on the multi-page data stored in the pre-program block based on the available memory capacity being less than the threshold.

6. The method of claim 5, comprising:
deallocating the digest data of the pre-program data from the digest memory.

7. The method of claim 1, comprising:
migrating the multi-page data stored in the pre-program block to a second memory block based on the available memory capacity being less than the threshold.

8. The method of claim 7, comprising:
deallocating digest data corresponding to the multi-page data stored in the pre-program block from the digest memory.

9. A storage device comprising:
a non-volatile memory device as a storage medium of the storage device;
a write buffer configured to temporarily store write data requested to be written from a host;
a digest memory configured to store digest data that writes the write data to the non-volatile memory device in a pre-program operation mode; and
a storage controller configured to:
determine a program mode of the write data as a pre-program operation mode based on an available memory capacity of the digest memory being greater than or equal to a threshold value,
program the write data in a first area of the non-volatile memory device according to the pre-program operation mode, and
generate the digest data corresponding to the write data.

10. The device of claim 9, wherein based on the available memory capacity of the digest memory being less than the threshold value, the storage controller is configured to program the write data in a second area in a normal program mode.

11. The device of claim 9, wherein the storage controller comprises:
a mode selector configured to determine the program mode according to the available memory capacity;
a re-program manager configured to perform a re-program operation of pre-programmed data stored in the first area based on the available memory capacity being less than the threshold; and
a recovery read manager configured to read out the pre-programmed data based on the digest data.

12. The device of claim 11, wherein the storage controller comprises a migration manager configured to migrate the pre-programmed data to a second area of the non-volatile memory device based on the digest data.

13. The device of claim 12, wherein the re-program manager or the migration manager is configured to invalidate the digest data corresponding to the pre-programmed data or migrated the pre-programmed data in the digest memory.

14. The device of claim 9, wherein the storage controller is configured to transmit a completion message of the write request to the host after the write data is programmed in the first area or after the digest data is stored in the digest memory.

15. The device of claim 9, wherein the storage controller is configured to release allocation of the write data from the write buffer after the write data is programmed in the first area.

16. A program method of a storage device, comprising:
receiving a write request of multi-page data from a host;
checking an available memory capacity of a digest memory;
setting a write mode of a non-volatile memory device to a pre-program mode based on the available memory capacity being greater than a threshold value;
programming the multi-page data into a pre-program block of the non-volatile memory device;
generating digest data from the multi-page data;
storing the digest data in the digest memory; and
transmitting a completion message for the write request to the host without re-programming the multi-page data.

17. The method of claim 16, comprising:
performing re-program operation on previously pre-programmed data in the pre-program block based on the available memory capacity being less than the threshold value.

18. The method of claim 17, comprising:
deallocating digest data corresponding to the previously pre-programmed data from the digest memory.

19. The method of claim 16, comprising:
migrating the previously pre-programmed data in the pre-program block to a second memory block based on the available memory capacity being less than the threshold value.

20. The method of claim 19, comprising:
deallocating digest data corresponding to the previously pre-programmed data from the digest memory.
